(19) United States
(12) Patent Application Publication
(10) Pub. No.: US 2023/0049647 A1
(43) Pub. Date: Feb. 16, 2023

(54) AMPLIFIER AND MEMORY

(71) Applicant: Changxin Memory Technologies, Inc., Hefei City (CN)

(72) Inventors: Yang Zhao, Hefei City (CN); Jaeyong Cha, Hefei City (CN)

(21) Appl. No.: 17/663,053

(22) Filed: May 12, 2022

(30) Foreign Application Priority Data
Aug. 13, 2021 (CN) 202110931846.7

(51) Int. Cl. G11C 11/4091; G11C 11/4094

(52) U.S. Cl. CPC G11C 11/4091; G11C 11/4094

(57) ABSTRACT

Embodiments of the present application relate to the field of semiconductors, and provide an amplifier and a memory. The amplifier includes at least a sense amplifier, where the sense amplifier includes a pull-up driving circuit and an amplifier circuit; the pull-up driving circuit includes one terminal connected to a power supply voltage, and the other terminal connected to a power supply terminal of the amplifier circuit; the sense amplifier includes a first sense amplifier and a second sense amplifier; the first sense amplifier includes a first pull-up driving circuit and a first amplifier circuit; the second sense amplifier includes a second pull-up driving circuit and a second amplifier circuit; and both the first pull-up driving circuit and the second pull-up driving circuit are located between the first amplifier circuit and the second amplifier circuit. The embodiments of the present application are helpful to improve the layout design of the amplifier.

### CROSS-REFERENCE TO RELATED APPLICATIONS

This application claims the priority of Chinese Patent Application No. 202110931846.7, submitted to the Chinese Intellectual Property Office on Aug. 13, 2021, the disclosure of which is incorporated herein in its entirety by reference.

### TECHNICAL FIELD

Embodiments of the present application relate to the field of semiconductors, and in particular, to an amplifier and a memory.

### BACKGROUND

A dynamic random access memory (DRAM) includes a plurality of word lines (WLs) and a plurality of bit lines (BLs) that are interdigitated. Memory cells composed of capacitors are connected to the WLs and the BLs. In response to a read operation of the memory cells, the WLs connected to the memory cells are activated, the state of charge (SOC) of the capacitors in the memory cells is applied to the BLs, a weak voltage signal is generated on the BL pair, and the amplifier circuit connected to the BL pair amplifies the weak voltage signal and transmits it to lower local input/output lines.

### SUMMARY

In an aspect, an embodiment of the present disclosure provides an amplifier, including: a sense amplifier, where the sense amplifier includes a pull-up driving circuit and an amplifier circuit; the pull-up driving circuit includes one terminal connected to a power supply voltage, and the other terminal connected to a power supply terminal of the amplifier circuit; the sense amplifier includes a first sense amplifier and a second sense amplifier; the first sense amplifier includes a first pull-up driving circuit and a first amplifier circuit; the second sense amplifier includes a second pull-up driving circuit and a second amplifier circuit; and both the first pull-up driving circuit and the second pull-up driving circuit are located between the first amplifier circuit and the second amplifier circuit.

In another aspect, an embodiment of the present application further provides a memory, including the amplifier described above.

### BRIEF DESCRIPTION OF THE DRAWINGS

One or more embodiments are exemplified by corresponding accompanying drawings, and these exemplified descriptions do not constitute a limitation on the embodiments. The accompanying drawings are not limited by scale unless otherwise specified.

FIG. 1 is a schematic diagram of a circuit structure of an amplifier according to an embodiment of the present application;

FIG. 2 is a schematic diagram of a layout structure of an amplifier according to an embodiment of the present application; and

FIG. 3 is a schematic structural diagram of a memory according to an embodiment of the present application.

### DETAILED DESCRIPTION

The embodiments of the present disclosure are described in detail below with reference to the drawings. Those of ordinary skill in the art should understand that many technical details are proposed in each embodiment of the present disclosure to help the reader better understand the present disclosure. However, even without these technical details and various changes and modifications made based on the following embodiments, the technical solutions claimed in the present disclosure may still be realized.

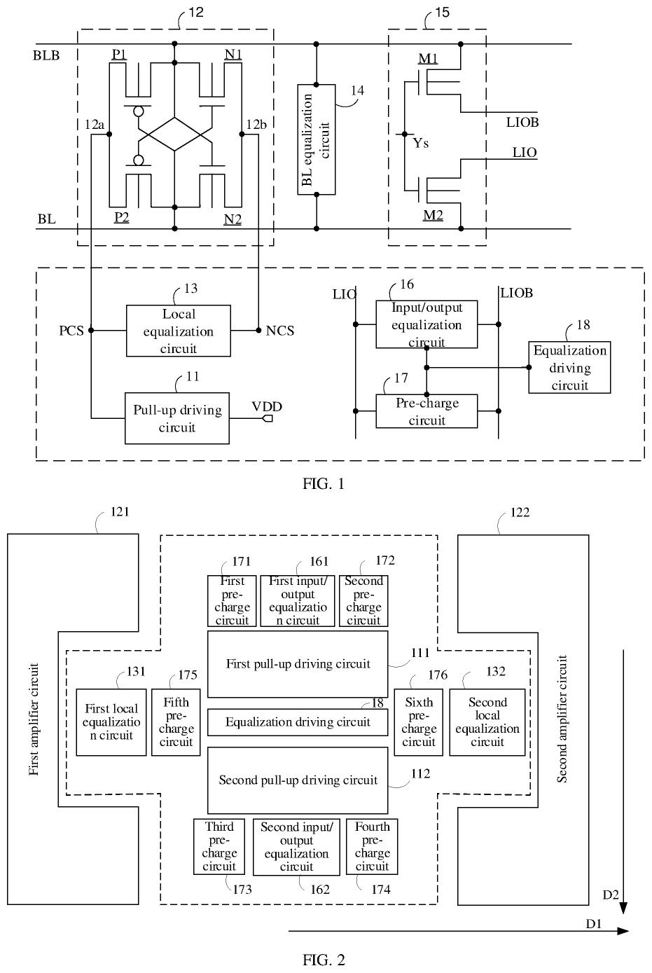

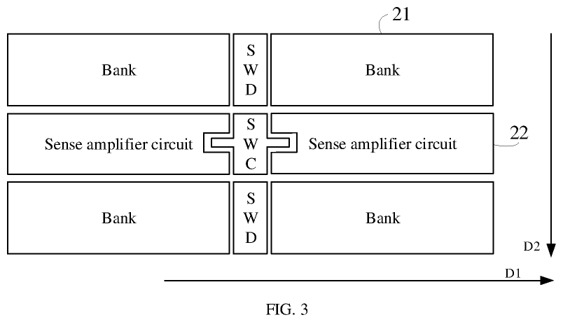

FIG. 1 is a schematic diagram of a circuit structure of an amplifier according to an embodiment of the present application. FIG. 2 is a schematic diagram of a layout structure of an amplifier according to an embodiment of the present application. FIG. 3 is a schematic structural diagram of a memory according to an embodiment of the present application.

Referring to FIG. 1 to FIG. 2, the amplifier includes a sense amplifier (not shown). The sense amplifier includes a pull-up driving circuit 11 and an amplifier circuit 12. The pull-up driving circuit 11 includes one terminal connected to a power supply voltage VDD, and the other terminal connected to a power supply terminal 12a of the amplifier circuit 12. The sense amplifier includes a first sense amplifier and a second sense amplifier. The first sense amplifier includes a first pull-up driving circuit 111 and a first amplifier circuit 121. The second sense amplifier includes a second pull-up driving circuit 112 and a second amplifier circuit 122. Both the first pull-up driving circuit 111 and the second pull-up driving circuit 112 are located between the first amplifier circuit 121 and the second amplifier circuit 122.

The embodiments of the present application will be described in more detail below with reference to the accompanying drawings.

Referring to FIG. 1, the amplifier circuit 12 includes a first positive-channel metal-oxide semiconductor (PMOS) transistor P1, a second PMOS transistor P2, a first negative-channel metal-oxide semiconductor (NMOS) transistor N1 and a second NMOS transistor N2. A drain of the P1 and a drain of the P2 are connected to the power supply terminal 12a. A source of the N1 and a source of the N2 are connected to a ground terminal 12b of the amplifier circuit 12. A gate of the P1, a gate of the N1, a source of the P2 and a drain of the N2 are connected to a BL. A gate of the P2, a gate of the N2, a source of the P1 and a drain of the N1 are connected to a bit line bar (BLB). In response to a standby state of the memory, the power supply terminal 12a and the ground terminal 12b of the amplifier circuit 12 are driven by an electrode line PCS/NCS to a pre-charge voltage same as that of the BL pair BL/BLB, such as VDD/2. In response to a read operation of the memory, corresponding WLs are activated, the SOC of capacitors is transferred to the BL pair BL/BLB, and a weak voltage signal is generated on the BL pair BL/BLB. In this case, by setting the voltage of the power supply terminal 12a as an internal step-down voltage through the electrode line PCS and setting the voltage of the ground terminal 12b as a ground voltage through the electrode line NCS, the amplifier circuit 12 is activated. The activated amplifier circuit 12 amplifies the weak voltage signal, and transmits the amplified read signal to a local input/output line LIO/a local input/output line bar LIOB.

In some embodiments, the amplifier further includes: a local equalization circuit 13, having one terminal connected to the power supply terminal 12a of the amplifier circuit 12, and the other terminal connected to the ground terminal 12b of the amplifier circuit 12; where the local equalization circuit 13 is configured to connect the power supply terminal 12a and the ground terminal 12b. In other words, the local equalization circuit 13 is configured to connect or disconnect the power supply terminal 12a and the ground terminal 12b of the amplifier circuit 12. In response to the standby state of the memory, the power supply terminal 12a and the ground terminal 12b are connected, and there are same voltage values on the power supply terminal 12a and the ground terminal 12b. In response to the read operation of the memory, the power supply terminal 12a and the ground terminal 12b are disconnected to activate the amplifier circuit 12.

The local equalization circuit 13 may include two transistors. Gates of the two transistors are configured to receive corresponding equalization signals of the local equalization circuit 13. The two transistors are connected to a common voltage, such that the power supply terminal 12a and the ground terminal 12b of the amplifier circuit 12 are connected to a same common voltage or disconnected.

In some embodiments, referring to FIG. 2, the first sense amplifier further includes a first local equalization circuit 131. The second sense amplifier further includes a second local equalization circuit 132. The first local equalization circuit 131 is located between the first pull-up driving circuit 111 and the first amplifier circuit 121. The second local equalization circuit 132 is located between the second pull-up driving circuit 112 and the second amplifier circuit 122. While the first pull-up driving circuit 111 and the second pull-up driving circuit 112 are used as the whole pull-up driving circuit 11, the first local equalization circuit 131 may be located at a middle position of a side of the pull-up driving circuit 11 close to the first amplifier circuit 121, and the second local equalization circuit 132 may be located at a middle position of a side of the pull-up driving circuit 11 close to the second amplifier circuit 122. The first local equalization circuit 131 and the second local equalization circuit 132 are axisymmetric with respect to the pull-up driving circuit 11.

An arrangement direction of the pull-up driving circuit 11 is perpendicular to an arrangement direction of the amplifier circuit 12. An arrangement direction of the local equalization circuit 13 is parallel to the arrangement direction of the amplifier circuit 12. Referring to FIG. 2, the amplifier is provided with a first direction D1 and a second direction D2 perpendicular to each other. The arrangement direction of the pull-up driving circuit 11 is a direction in which the first pull-up driving circuit 111 faces toward the second pull-up driving circuit 112. The arrangement direction of the amplifier circuit 12 is a direction in which the first amplifier circuit 121 faces toward the second amplifier circuit 122. The arrangement direction of the local equalization circuit 13 is a direction in which the first local equalization circuit 131 faces toward the second local equalization circuit 132. Both the arrangement direction of the amplifier circuit 12 and the arrangement direction of the local equalization circuit 13 are the first direction D1, and the arrangement direction of the pull-up driving circuit 11 is the second direction D2.

Further, the pull-up driving circuit 11 may be a transistor, including a drain for connecting the power supply voltage VDD, and a gate for receiving a control signal to connect or disconnect a source and the drain of the transistor. The arrangement direction of the local equalization circuit 13 is perpendicular to the arrangement direction of the pull-up driving circuit 11, such that a larger space is reserved in the arrangement direction of the pull-up driving circuit 11 to prepare a transistor having a wider gate. Therefore, the conduction rate of the transistor and the voltage pull-up rate for the power supply terminal 12a of the amplifier circuit 12 are improved to accelerate a read rate of the memory. It is to be noted that the embodiment of the present application only takes the pull-up driving circuit 11 as the transistor to illustrate the effect of the reserved space. In other embodiments, the pull-up driving circuit 11 may further include other functional components. The larger space reserved in the arrangement direction of the pull-up driving circuit 11 can be favorable to improve performance of the pull-up driving circuit 11.

In some embodiments, referring to FIG. 1, the amplifier further includes: a BL equalization circuit 14, having one terminal connected to the BL and the other terminal connected to the BLB, where the BL equalization circuit 14 is configured to connect the BL and the BLB. The BL equalization circuit 14 may be a transistor. A gate of the transistor is configured to receive a corresponding BL equalization signal of the BL equalization circuit 14, to connect or disconnect the BL pair BL/BLB. In response to the standby state of the memory, the BL equalization circuit 14 connects the BL pair BL/BLB based on a BL equalization signal, such that voltages on the BL and the BLB are the same.

Further, the BL equalization circuit 14 is frequently connected to a BL pre-charge circuit, such that voltages on the BL and the BLB are at a reference voltage such as VDD/2 in the standby state. The BL pre-charge circuit may include two transistors. A source of one transistor is connected to the BL. A source of the other transistor is connected to the BLB. A drain of each of the two transistors receives the pre-charge voltage, and a gate of each of the two transistors receives the BL equalization signal. In response to a BL equalization signal received by the memory, both the BL and the BLB are charged through the pre-charge voltage. In this case, the BL and the BLB are connected through the BL equalization circuit 14, which ensures the same voltages on the BL and the BLB and avoids the voltage difference between the BL and the BLB.

In some embodiments, referring to FIG. 1, the amplifier further includes: a column switch circuit 15, connected to the BL and the BLB as well as the local input/output line LIO and the local input/output line bar LIOB; where the column switch circuit 15 is configured to receive a column selection signal Ys, connect or disconnect the local input/output line LIO and the BL based on the column selection signal Ys, and connect or disconnect the local input/output line bar LIOB and the BLB based on the column selection signal Ys.

The column switch circuit 15 includes a first transistor M1 and a second transistor M2. The first transistor M1 is configured to connect the local input/output line LIO and the BL. The second transistor M2 is configured to connect the local input/output line bar LIOB and the BLB. A gate of the first transistor M1 and a gate of the second transistor M2 are configured to receive the column selection signal Ys. The column selection signal Ys is controlled by a column decoder, so as to selectively read a weak voltage signal of a BL pair that is actually needed and connected to the activated WL. When sources and drains of the first transistor M1 and the second transistor M2 are connected, the weak voltage signal amplified by the amplifier circuit 12 is transmitted to a local input/output line pair LIO/LIOB through the BL pair BL/BLB.

The first transistor M1 and the second transistor M2 each may be a PMOS transistor, and may also be an NMOS transistor. Exemplarily, the first transistor M1 and the second transistor M2 each are the NMOS transistor, and the column selection signal Ys includes an internal boosting voltage.

In some embodiments, the amplifier further includes: an input/output equalization circuit 16, having one terminal connected to the local input/output line LIO, and the other terminal connected to the local input/output line bar LIOB; where the input/output equalization circuit 16 is configured to connect the local input/output line LIO and the local input/output line bar LIOB. Similar to the BL equalization circuit 14, the input/output equalization circuit 16 connects or disconnects the local input/output line LIO and the local input/output line bar LIOB based on a corresponding input/output equalization signal, such that voltages on the local input/output line LIO and the local input/output line bar LIOB are the same in the standby state of the memory.

Referring to FIG. 2, the first sense amplifier further includes a first input/output equalization circuit 161. The second sense amplifier further includes a second input/output equalization circuit 162. In the arrangement direction of the pull-up driving circuit, the first input/output equalization circuit 161, the first pull-up driving circuit 111, the second pull-up driving circuit 112 and the second input/output equalization circuit 162 are sequentially arranged. That is, the local equalization circuit 13 and the input/output equalization circuit 16 are located on different sides of the pull-up driving circuit 11.

In some embodiments, referring to FIG. 1, the amplifier further includes: a pre-charge circuit 17, having one terminal connected to the local input/output line LIO, and the other terminal connected to the local input/output line bar LIOB, where the pre-charge circuit 17 is configured to pre-charge the local input/output line LIO and the local input/output line bar LIOB. The pre-charge circuit 17 is functionally and structurally similar to the BL pre-charge circuit mentioned above, namely a source of one transistor is connected to the local input/output line LIO, a source of the other transistor is connected to the local input/output line bar LIOB, a drain of each of the two transistors receives a pre-charge voltage, and a gate of each of the two transistors receives an input/output equalization signal. The pre-charge voltage may be the power supply voltage VDD, namely the pull-up driving circuit 11 is further connected to the pre-charge circuit 17 through the electrode line PCS.

In some embodiments, the first sense amplifier further includes a first pre-charge circuit 171 and a second pre-charge circuit 172. The second sense amplifier further includes a third pre-charge circuit 173 and a fourth pre-charge circuit 174. In the arrangement direction of the amplifier circuit 12, the first pre-charge circuit 171 and the second pre-charge circuit 172 are located on two opposite sides of the first input/output equalization circuit 161, and the third pre-charge circuit 173 and the fourth pre-charge circuit 174 are located on two opposite sides of the second input/output equalization circuit 162.

As is obvious from the figure, the first pre-charge circuit 171, the second pre-charge circuit 172 and the first input/output equalization circuit 161 are located on a same side of the first pull-up driving circuit 111. In order to achieve a regular contour of the amplifier, a total width for the first pre-charge circuit 171, the second pre-charge circuit 172 and the first input/output equalization circuit 161 is less than or equal to a width of the first pull-up driving circuit 111 in the first direction D1. Similarly, the third pre-charge circuit 173, the fourth pre-charge circuit 174 and the second input/output equalization circuit 162 are located on a same side of the second pull-up driving circuit 112. A total width for the third pre-charge circuit 173, the fourth pre-charge circuit 174 and the second input/output equalization circuit 162 is less than or equal to a width of the second pull-up driving circuit 112 in the first direction D1.

In some embodiments, the first sense amplifier further includes a fifth pre-charge circuit 175. The second sense amplifier further includes a sixth pre-charge circuit 176. The fifth pre-charge circuit 175 is located between the first pull-up driving circuit 111 and the first amplifier circuit 121. The sixth pre-charge circuit 176 is located between the second pull-up driving circuit 112 and the second amplifier circuit 122. As is obvious from the figure, the above positional relationship may also be described as follows: The fifth pre-charge circuit 175 is located between the second pull-up driving circuit 112 and the first amplifier circuit 121, and the sixth pre-charge circuit 176 is located between the first pull-up driving circuit 111 and the second amplifier circuit 122. Or, by viewing the first pull-up driving circuit 111 and the second pull-up driving circuit 112 between adjacent amplifier circuits 12 as the whole pull-up driving circuit 11, the fifth pre-charge circuit 175 is located between the pull-up driving circuit 11 and the first amplifier circuit 121, and the sixth pre-charge circuit 176 is located between the pull-up driving circuit 11 and the second amplifier circuit 122. An arrangement direction of each of the fifth pre-charge circuit 175 and the sixth pre-charge circuit 176 is the first direction D1, and is the same as the arrangement direction of the local equalization circuit 13.

Further, the fifth pre-charge circuit 175 is located between the first pull-up driving circuit 111 and the corresponding first local equalization circuit 131, and the sixth pre-charge circuit 176 is located between the second pull-up driving circuit 112 and the corresponding second local equalization circuit 132. By viewing the first pull-up driving circuit 111 and the second pull-up driving circuit 112 as a whole, the fifth pre-charge circuit 175 is located between the pull-up driving circuit 11 and the corresponding first local equalization circuit 131, and the sixth pre-charge circuit 176 is located between the pull-up driving circuit 11 and the corresponding second local equalization circuit 132.

Further, the amplifier further includes: an equalization driving circuit 18, connected to the input/output equalization circuit 16 and the pre-charge circuit 17. The equalization driving circuit 18 is configured to output a local input/output equalization signal to the input/output equalization circuit 16 and the pre-charge circuit 17, such that the pre-charge circuit 17 charges the local input/output line LIO and the local input/output line bar LIOB and achieves same voltages on the local input/output line LIO and the local input/output line bar LIOB through the input/output equalization circuit 16.

In some embodiments, the equalization driving circuit 18 is located between the first pull-up driving circuit 111 and the second pull-up driving circuit 112. It is to be noted that different sense amplifiers may share the same equalization driving circuit 18 or may be respectively provided with the equalization driving circuit 18. If different sense amplifiers are respectively provided with the equalization driving circuit 18, for example, the first sense amplifier is provided with a first equalization driving circuit, and the second sense amplifier is provided with a second equalization driving circuit, the first equalization driving circuit and the second equalization driving circuit are located between the first pull-up driving circuit 111 and the second pull-up driving circuit 112, and an arrangement direction of each of the first equalization driving circuit and the second equalization driving circuit may be perpendicular or parallel to the arrangement direction of the pull-up driving circuit 11 in some embodiments.

In the embodiment of the present application, by providing the first pull-up driving circuit and the second pull-up driving circuit between the first amplifier circuit and the second amplifier circuit, there are an even number of similar circuit devices between the first amplifier circuit and the second amplifier circuit, including the pull-up driving circuit and other connected circuit devices such as the local equalization circuit. The even number of similar circuit devices is helpful to improve the layout design, make the layout design more symmetrical and achieve better corresponding electrical properties.

An embodiment of the present disclosure further provides a memory, including the amplifier descried above.

Referring to FIG. 3, the memory includes a plurality of banks 21 arranged in an array. The banks 21 are arranged along the first direction D1 and the second direction D2. Adjacent banks 21 along the first direction D1 are provided therebetween with sub-WL drivers SWD. Adjacent banks 21 along the second direction D2 are provided therebetween with sense amplifier circuits 22. Switch circuits SWC are respectively provided between adjacent sense amplifier circuits 22 and adjacent sub-WL drivers SWD.

Referring to FIG. 1 and FIG. 3, the pull-up driving circuit 11, the local equalization circuit 13, the input/output equalization circuit 16, the pre-charge circuit 17 and the equalization driving circuit 18 shown in FIG. 1 are located in the switch circuits SWC shown in FIG. 3. The amplifier circuits shown in FIG. 1 are located in the sense amplifier circuits 22 shown in FIG. 3. In other words, the sense amplifiers each include at least a part of switch circuits SWC and a part of sense amplifier circuits 22. As the local equalization circuit 13 and a part of pre-charge circuit 17 are located between the pull-up driving circuit 11 and the amplifier circuit 12, the switch circuits SWC appear cross-shaped. A part of switch circuits SWC extend to the sense amplifier circuits 22, or a part of switch circuits SWC are located between adjacent banks 21 extending along the second direction D2. By extending a part of switch circuits SWC to the sense amplifier circuits 22, a larger adjustment space is reserved for the switch circuits SWC in the second direction D2 to improve the layout design of the switch circuits SWC and key dimensions of components in the switch circuits SWC, thereby achieving better electrical properties of the switch circuits SWC, such as the conduction rates.

Those of ordinary skill in the art can understand that the above implementations are specific embodiments for implementing the present application. In practical applications, various changes may be made to the above embodiments in terms of form and details without departing from the spirit and scope of the present application. Any person skilled in the art may make changes and modifications to the embodiments without departing from the spirit and scope of the present disclosure. Therefore, the protection scope of the present disclosure should be subject to the scope defined by the claims.

1. An amplifier, comprising:
a sense amplifier, wherein the sense amplifier comprises a pull-up driving circuit and an amplifier circuit, and the pull-up driving circuit comprises one terminal connected to a power supply voltage, and the other terminal connected to a power supply terminal of the amplifier circuit; and
the sense amplifier comprises a first sense amplifier and a second sense amplifier, the first sense amplifier comprises a first pull-up driving circuit and a first amplifier circuit, the second sense amplifier comprises a second pull-up driving circuit and a second amplifier circuit, and both the first pull-up driving circuit and the second pull-up driving circuit are located between the first amplifier circuit and the second amplifier circuit.

2. The amplifier according to claim 1, wherein the amplifier circuit comprises a first positive-channel metal-oxide semiconductor (PMOS) transistor, a second PMOS transistor, a first negative-channel metal-oxide semiconductor (NMOS) transistor and a second NMOS transistor; a drain of the first PMOS transistor and a drain of the second PMOS transistor are connected to the power supply terminal; a source of the first NMOS transistor and a source of the second NMOS transistor are connected to a ground terminal of the amplifier circuit; a gate of the first PMOS transistor, a gate of the first NMOS transistor, a source of the second PMOS transistor and a drain of the second NMOS transistor are connected to a bit line; and a gate of the second PMOS transistor, a gate of the second NMOS transistor, a source of the first PMOS transistor and a drain of the first NMOS transistor are connected to a bit line bar.

3. The amplifier according to claim 1, further comprising: a local equalization circuit, having one terminal connected to the power supply terminal of the amplifier circuit, and the other terminal connected to a ground terminal of the amplifier circuit, wherein the local equalization circuit is configured to connect the power supply terminal and the ground terminal.

4. The amplifier according to claim 3, wherein the first sense amplifier further comprises a first local equalization circuit, the second sense amplifier further comprises a second local equalization circuit, the first local equalization circuit is located between the first pull-up driving circuit and the first amplifier circuit, and the second local equalization circuit is located between the second pull-up driving circuit and the second amplifier circuit.

5. The amplifier according to claim 4, wherein an arrangement direction of the pull-up driving circuit is perpendicular to an arrangement direction of the amplifier circuit, and an arrangement direction of the local equalization circuit is parallel to the arrangement direction of the amplifier circuit.

6. The amplifier according to claim 2, further comprising: a bit line equalization circuit, having one terminal connected to the bit line, and the other terminal connected to the bit line bar, wherein the bit line equalization circuit is configured to connect the bit line and the bit line bar.

7. The amplifier according to claim 2, further comprising: a column switch circuit, connected to the bit line and the bit line bar as well as a local input/output line and a local input/output line bar; wherein the column switch circuit is configured to receive a column selection signal, connect or disconnect the local input/output line and the bit line based on the column selection signal, and connect or disconnect the local input/output line bar and the bit line bar based on the column selection signal.

8. The amplifier according to claim 7, wherein the column switch circuit comprises a first transistor and a second transistor, the first transistor is configured to connect the local input/output line and the bit line, the second transistor is configured to connect the local input/output line bar and the bit line bar, and a gate of the first transistor and a gate of the second transistor each is configured to receive the column selection signal.

9. The amplifier according to claim 7, further comprising: an input/output equalization circuit, having one terminal connected to the local input/output line, and the other terminal connected to the local input/output line bar, wherein the input/output equalization circuit is configured to connect the local input/output line and the local input/output line bar.

10. The amplifier according to claim 9, wherein the first sense amplifier further comprises a first input/output equalization circuit; the second sense amplifier further comprises a second input/output equalization circuit; and in an arrangement direction of the pull-up driving circuit, the first input/output equalization circuit, the first pull-up driving circuit, the second pull-up driving circuit and the second input/output equalization circuit are sequentially arranged.

11. The amplifier according to claim 10, further comprising: a pre-charge circuit, having one terminal connected to the local input/output line, and the other terminal connected to the local input/output line bar, wherein the pre-charge circuit is configured to pre-charge the local input/output line and the local input/output line bar.

12. The amplifier according to claim 11, wherein the first sense amplifier further comprises a first pre-charge circuit and a second pre-charge circuit; the second sense amplifier further comprises a third pre-charge circuit and a fourth pre-charge circuit; and in the arrangement direction of the amplifier circuit, the first pre-charge circuit and the second pre-charge circuit are located on two opposite sides of the first input/output equalization circuit, and the third pre-charge circuit and the fourth pre-charge circuit are located on two opposite sides of the second input/output equalization circuit.

13. The amplifier according to claim 12, wherein the first sense amplifier further comprises a fifth pre-charge circuit, the second sense amplifier further comprises a sixth pre-charge circuit, the fifth pre-charge circuit is located between the first pull-up driving circuit and the first amplifier circuit, and the sixth pre-charge circuit is located between the second pull-up driving circuit and the second amplifier circuit.

14. The amplifier according to claim 13, wherein the fifth pre-charge circuit is located between the first pull-up driving circuit and a corresponding first local equalization circuit, and the sixth pre-charge circuit is located between the second pull-up driving circuit and a corresponding second local equalization circuit.

15. The amplifier according to claim 11, further comprising: an equalization driving circuit, connected to the input/output equalization circuit and the pre-charge circuit, wherein the equalization driving circuit is located between the first pull-up driving circuit and the second pull-up driving circuit.

16. A memory, comprising the sense amplifier according to claim 1.
